(19) United States
(12) Patent Application Publication
(10) Pub. No.: US 2020/0161356 A1
(43) Pub. Date: May 21, 2020

(54) CAMERA ASSEMBLY AND PACKAGING METHOD, LENS MODULE AND ELECTRONIC DEVICE

(71) Applicant: Ningbo Semiconductor International Corporation, Ningbo (CN)

(72) Inventors: Da CHEN, Ningbo (CN); Mengbin LIU, Ningbo (CN)

(21) Appl. No.: 16/235,065

(22) Filed: Dec. 28, 2018

Related U.S. Application Data
(63) Continuation of application No. PCT/CN2018/119987, filed on Dec. 10, 2018.

(30) Foreign Application Priority Data
Nov. 20, 2018 (CN) 201811385636.7

(51) Int. Cl. H01L 27/146; H04N 5/225; G02B 5/20; H01L 25/16; H01L 23/492; H01L 23/31

(52) U.S. Cl. CPC H01L 27/14625; H04N 5/2254; H04N 5/2252; H01L 23/3121; H01L 25/167; H01L 23/492; G02B 5/20

(57) ABSTRACT

Camera assemblies and packaging methods, lens modules and electronic devices are provided. An exemplary packaging method of the camera assembly includes providing a photosensitive chip having a soldering pad and a filter; mounting the filter to the photosensitive chip with the filter facing the soldering pad of the photosensitive chip; providing a first carrier substrate and temporarily bonding functional components and the filter on the first carrier substrate, wherein the functional component contains a soldering pad facing the first carrier substrate; forming an encapsulation layer to cover the first carrier substrate and the functional components, and at least cover portions of sidewall surfaces of the photosensitive chip; removing the first carrier substrate; and forming a re-distribution layer structure on a side of the encapsulation layer adjacent to the filter to electrically connect the soldering pad of the photosensitive chip and the soldering pad of the functional component.

### CROSS-REFERENCES TO RELATED APPLICATIONS

This application is a continuation application of PCT patent application No. PCT/CN2018/119987, filed on Dec. 10, 2018, which claims priority to Chinese patent application No. 201811385636.7, filed on Nov. 20, 2018, the entirety of all of which is incorporated herein by reference.

### FIELD OF THE DISCLOSURE

The present disclosure generally relates to the field of lens modules and, more particularly, relates to camera assemblies and packaging methods of camera assemblies, lens modules and electronic devices.

### BACKGROUND

With the continuous improvement of people's living standards and abundance of hobbies, photo-capturing has gradually become a common means for people to record their outing and various aspects of their daily life. Thus, electronic devices (e.g., mobile phones, tablets and cameras) with camera functions are widely used in people's daily life and work, and gradually become indispensable tools nowadays.

Electronic devices with camera functions are often configured with a lens module. The design level of the lens modules plays an important role for determining quality of photographs taken by the electronic devices. The lens module often includes a camera assembly having a photosensitive chip and a lens assembly mounted on the camera assembly, used to capture images of photographed objects.

Further, to improve the imaging capability of the lens module, the photosensitive chip is often required for a larger imaging area. Passive components, such as resistors and capacitors and peripheral chips, are also often disposed in the lens module.

### BRIEF SUMMARY OF THE DISCLOSURE

The present disclosure provides camera assemblies, and packaging methods of camera assemblies, lens modules, and electronic devices to improve the performance of the lens modules and reduce the total thickness of the lens modules.

The present disclosure provides a method for packaging a camera assembly. The method may include providing a photosensitive chip and a filter. The photosensitive chip may include a soldering pad. The method may also include mounting the filter on the photosensitive chip with the filter facing the soldering pad of the photosensitive chip. Further, the method may include providing a first carrier substrate. Functional components and the filter may be temporarily bonded on the first carrier substrate. The functional component may have a soldering pad; and the soldering pad of the functional component may face the first carrier substrate. Further, the method may include forming an encapsulation layer to cover the first carrier substrate and the functional components, and at least portions of the sidewall surfaces of the photosensitive chip. Further, the method may include removing the first carrier substrate; and forming a re-distribution layer structure on a side of the encapsulation layer adjacent to the filter to electrically connect the soldering pad of the photosensitive chip and the soldering pad of the functional component.

The present disclosure also provides a camera assembly. The camera assembly may include an encapsulation layer, and a photosensitive unit and functional components embedded in the encapsulation layer. The photosensitive unit may include a photosensitive chip and a filter mounted on the photosensitive chip. A bottom surface of the encapsulation layer may be higher than the functional components, and the encapsulation layer may cover at least portions of the sidewall surfaces of the photosensitive chip. The photosensitive chip and the functional components may all contain soldering pads. The soldering pad of the photosensitive chip may face a top surface of the encapsulation layer. The soldering pads of the functional components may be exposed on the top surface of the encapsulation layer. The camera assembly may also include a re-distribution layer structure disposed on a side of the encapsulation layer adjacent to the filter layer. The redistribution structure may electrically connect the soldering pads.

The present disclosure also provides a lens module. The lens module may include the camera assembly according to various disclosed embodiments and a lens assembly. The lens assembly may include a support, and the support may be mounted on the top surface of the encapsulation layer and surround the photosensitive unit and the functional components. The lens assembly, the photosensitive chip and the functional device may be electrically connected.

The present disclosure also provides an electronic device. The electronic device may include the lens module according to various disclosed embodiments.

Other aspects of the present disclosure can be understood by those skilled in the art in light of the description, the claims, and the drawings of the present disclosure.

### BRIEF DESCRIPTION OF THE DRAWINGS

The following drawings are merely examples for illustrative purposes according to various disclosed embodiments, and are not intended to limit the scope of present disclosure.

FIGS. 1-16 illustrate structures corresponding to certain steps of during an exemplary packaging method of a camera assembly consistent with various disclosed embodiments;

FIGS. 17-20 illustrate structures corresponding to certain steps of during another exemplary packaging method of a camera assembly consistent with various disclosed embodiments;

FIG. 21 illustrates an exemplary lens module consistent with various disclosed embodiments; and

FIG. 22 illustrates an exemplary electronic device consistent with various disclosed embodiments.

### DETAILED DESCRIPTION

Currently, the performance of the lens module needs to be improved, and the lens module is difficult to meet the requirements of miniaturization and thinning of the lens module. The reasons may be as following.

The conventional lens module may be mainly assembled with a circuit board, a photosensitive chip, functional components (for example, a peripheral chip), and a lens assembly. The peripheral chip may be often mounted on a peripheral motherboard, and the photosensitive chip and the functional components may be separated from each other. The circuit board may be used to support the photosensitive chip, and the electrical connections among the photosensitive chip, the functional component and the lens module may be realized by using the circuit board.

However, with the requirements of high-pixel and ultra-thin lens module, the imaging requirements of the lens module have been higher and higher, the area of the photosensitive chip may be correspondingly increased, and the functional components may be correspondingly increased. Thus, the size of the lens module has become larger and larger; and it may be difficult to meet the needs of miniaturization and thinning of the lens module. Moreover, the photosensitive chip may be often disposed inside the support in the lens assembly, and the peripheral chip may be usually disposed outside the support. Thus, there may be a certain distance between the peripheral chip and the photosensitive chip; and the signal transmission rate may be reduced. The peripheral chip usually includes a digital signal processor (DSP) chip and a memory chip. Thus, it may be easy to adversely affect the imaging speed and the storage speed, and the performance of the lens module may be reduced.

The present disclosure may integrate the photosensitive chip and the functional components into the encapsulation layer, and realize electrical connections by using a re-distribution layer structure. Comparing with the scheme of mounting the functional components on the peripheral main board, the distance between the functional components and the photosensitive chip may be reduced, and the electrical connection distance between the photosensitive chip and the functional components may be correspondingly reduced. Accordingly, the signal transmission speed may be significantly increased, and the performance of the lens module may be improved. Further, by using the encapsulation layer and the re-distribution layer structure, the circuit board may be correspondingly eliminated. Thus, the total thickness of the lens module may be reduced, and the needs of miniaturization and thinning of the lens module may be met.

To allow the described objects, features and advantages of the present disclosure to be more apparent from the aspects of the appended claims, the specific embodiments of the present disclosure will be described in detail below with reference to the accompanying drawings.

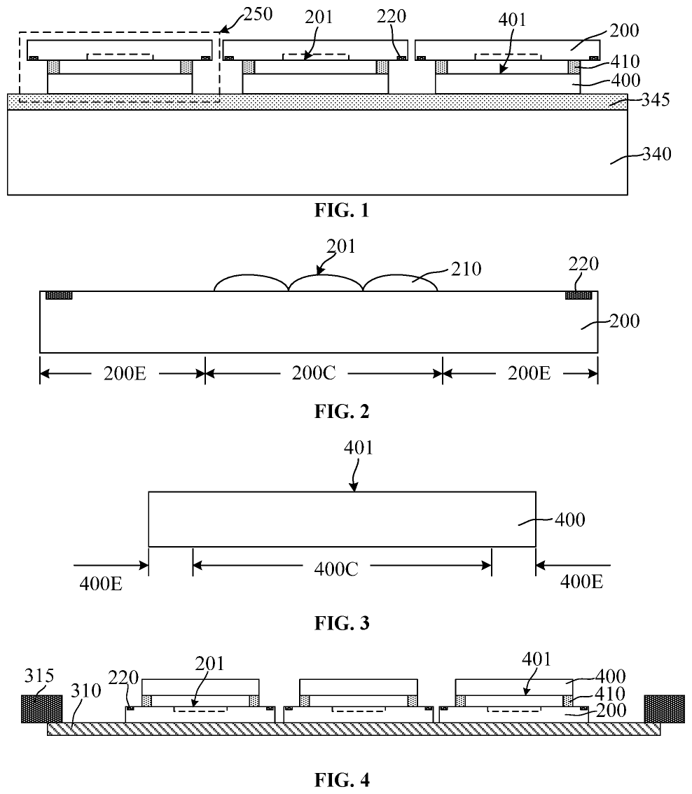

FIGS. 1-16 illustrate structures corresponding to certain stages during an exemplary packaging method of a camera assembly according to various disclosed embodiments.

Referring to FIGS. 1-3, FIG. 2 is an enlarged view of a photosensitive chip in FIG. 1, and FIG. 3 is an enlarged view of a filter in FIG. 1. As shown in FIGS. 1-3, the packaging method may include providing a photosensitive chip 200 and a filter 400. The photosensitive chip 200 may have a soldering pad (not labeled). The filter 400 may be mounted on the photosensitive chip 200, and the filter 400 may face the soldering pad of the photosensitive chip 200.

The photosensitive chip 200 may be an imaging sensor chip. In one embodiment, the photosensitive chip 200 is a CMOS imaging sensor (CIS) chip. In some embodiments, the photosensitive chip may also be a charge-coupled-device (CCD) imaging sensor chip.

In one embodiment, the photosensitive chip 200 may have an optical signal receiving surface 201 (as shown in FIG. 2), and the photosensitive chip 200 may sense and receive the optical radiation signal through the optical signal receiving surface 201. In particular, as shown in FIG. 2, the photosensitive chip 200 may include a photosensitive region 200C and a peripheral region 200E surrounding the photosensitive region 200C, and the optical signal receiving surface 201 may be disposed in the photosensitive region 200C.

The photosensitive chip 200 may include a plurality of pixel units. Thus, the photosensitive chip 200 may include a plurality of semiconductor photosensitive devices (not shown), and a plurality of filter films (not shown) on the semiconductor photosensitive devices. The filter films may be used to selectively absorb and transmit the optical signals received by the optical signal receiving surface 201. The photosensitive chip 200 may also include micro-lenses 210 on the filter films, and the micro-lenses 210 may be in one-to-one correspondence with the semiconductor photosensitive devices. Thus, the received optical radiation signal light may be focused onto the semiconductor photosensitive devices. The optical signal receiving surface 201 may corresponds to a top surface of the micro-lens 210.

The photosensitive chip 200 may often be a silicon-based chip, and may be fabricated by an integrated circuit fabrication technique. The photosensitive chip 200 may have soldering pads for electrically connecting the photosensitive chip 200 to other chips or components. In one embodiment, the photosensitive chip 200 include a first soldering pad 220 formed in the peripheral region 200E. In particular, the surface of the photosensitive chip 200 on the same side of the optical signal receiving surface 201 may expose the first soldering pad 220.

The filter 400 may be mounted on the photosensitive chip 200 to prevent the subsequent packaging process from polluting the optical signal receiving surface 201. Further, such as configuration may facilitate to reduce the overall thickness of the subsequently described lens module to meet the requirements for miniaturization and thinning of the lens module.

The filter 400 may be an infrared filter glass sheet or a fully transparent glass sheet. In one embodiment, the filter 400 is an infrared filter glass sheet for eliminating the influence of the infrared light in the incident light on the performance of the photosensitive chip 200.

In particular, the filter 400 may an infrared cut filter (IRCF), and the infrared cut filter may be a blue glass infrared cut filter. The infrared cut filter may also include a glass substrate and an IR cut coating on the glass surface.

In one embodiment, the filter 400 may include a mounting surface 401 (as shown in FIG. 1). The mounting surface 401 may be a surface for mounting the filter 400 with the photosensitive chip 200, i.e., a surface facing the photosensitive chip 200.

In particular, for the case where the filter 400 is a blue glass infrared cut filter, one surface of the blue glass infrared cut filter may be coated with a transparent-enhancement film or an antireflection film, and the surface opposing to the surface having the transparent-enhancement film or the antireflection film may be the mounting surface 401. For the case where the filter 400 having the glass substrate and the infrared cut film on the glass surface, the glass surface opposing to the infrared cut film may be the mounting surface 401. In some embodiments, when the filter is a fully transparent glass sheet, either surface of the fully transparent glass sheet may be a mounting surface.

As shown in FIG. 3, the filter 400 may include a light transmitting region 400C and an edge region 400E surrounding the light transmitting region 400C. After the lens module is formed, the light transmitting region 400C may be configured to transmit external incident light such that the optical signal receiving surface 201 may receive the optical signals to ensure the normal function of the lens module. The edge region 400E may reserve spaces for mounting the filter 400 and the photosensitive chip 200.

In one embodiment, after the filter 400 is mounted to the photosensitive chip 200, the filter 400 and the photosensitive chip 200 may form a photosensitive unit 250 (as shown in FIG. 1).

Further, as shown in FIG. 1, in one embodiment, the filter 400 may be mounted on the photosensitive chip 200 through an adhesive structure 410. The adhesive structure 410 may surround the optical signal receiving surface 201.

The adhesive structure 410 may be used to form a physical connection between the filter 400 and the photosensitive chip 200. Further, the filter 400, the adhesive structure 410, and the photosensitive chip 200 together may form a cavity (not labeled) to prevent the filter 400 from directly contacting with the photosensitive chip 200. Accordingly, the adverse effect of the filter 400 on the performance of the photosensitive chip 200 may be prevented.

In one embodiment, the adhesive structure 410 may surround the optical signal receiving surface 201 such that the optical filter 400 above the optical signal receiving surface 201 may be disposed on the photo-sensing path of the photosensitive chip 200.

In particular, the adhesive structure 410 may be made a photolithographic material, and the adhesive structure 410 may be formed by a photolithography process. Thus, the morphological quality and the dimensional accuracy of the adhesive structure 410 may be improved; and the packaging efficiency and the production capacity may be enhanced as well. Further, the impact of the adhesive structure 410 on the bonding strength may be improved. In one embodiment, the adhesive structure 410 may be made of a photolithographic dry film. In some embodiments, the adhesive structure may also be made of a photolithographic polyimide, a photolithographic polybenzoxazole (PBO), or a photolithographic benzocyclobutene (BCB), etc.

In one embodiment, to reduce the process difficulty for forming the adhesive structure 410 and reduce the influence of the formation of the adhesive structure 410 on the optical signal receiving surface 201, the adhesive structure 410 may be formed on the filter 400.

In particular, as shown in FIG. 1, the process for mounting the filter 400 on the photosensitive chip 200 may include providing a third carrier substrate 340; temporally bonding the surface of the filter 400 away from the mounting surface 401 to the third carrier substrate 340; forming a ring-shaped adhesive structure on the edge region 400E of the filter 400 after the temporal bonding process; and turning the optical signal receiving surface 201 of the photosensitive chip 200 to face the ring-shaped adhesive structure 410 and mounting the peripheral region 200E of the photosensitive chip 200 (as shown in FIG. 2) to the ring-shaped adhesive structure 410 to form the photosensitive unit 250.

The third carrier substrate 340 may be used to provide a process platform for the mounting step to improve the process operability. In one embodiment, the third carrier substrate 340 is a carrier wafer. In some embodiments, the third carrier substrate may also be other types of substrates.

In particular, the filter 400 may be temporarily mounted to the third carrier substrate 340 through a first temporary bonding layer 345. The first temporary bonding layer 345 may be used as a peeling layer to facilitate a subsequent de-bonding process.

In one embodiment, the first temporary bonding layer 345 is a foamed film. The foamed film may include a micro-adhesive surface and an opposing foaming surface. The foamed film may have a certain viscosity at a room temperature, and the foamed surface may be attached to the third carrier substrate 340. The foamed film may be subsequently heated to cause the foaming surface to lose its adhesive property and thus achieve a de-bonding. In some embodiments, the first temporary bonding layer may also be a die attach film (DAF).

Further, as shown in FIG. 4, it should be noted that, after the mounting process, the surface of the photosensitive chip 200 opposing to the optical signal receiving surface 201 may be bonded to an UV film 310. Then, a first de-bonding process may be performed to remove the third carrier substrate 340 (as shown in FIG. 1).

Through the mounting process, a process preparation is performed for subsequently temporarily mounting the photosensitive unit 250 (shown in FIG. 1) on another carrier substrate. Further, the UV film 310 may be used to support and fix the photosensitive unit 250 after removing the third carrier substrate 340. The adhesion of the UV film 310 may be weakened under an ultraviolet light. Thus, it may be easy for subsequently separating the photosensitive unit 250 from the UV film 310.

In particular, the UV film 310 may be attached to the surface of the photosensitive chip 200 facing away from the optical signal receiving surface 201 by a film applicator, and may also be attached to the bottom of the support 315 having a larger diameter. Through the support 315, the UV film 310 may be stretched such that the photosensitive unit 250 may be separately fixed to the UV film 310. The detailed description of the UV film 310 and the support 315 will not be repeated herein.

In one embodiment, the first temporary bonding layer 345 (as shown in FIG. 1) is a foamed film. Thus, during the first de-bonding process, the first temporary bonding layer 345 may be heat-treated to cause the foamed face of the foamed film to lose its tackiness. Accordingly, the third carrier substrate 340 may be removed, and then the first temporary bonding layer 345 may be removed by tearing.

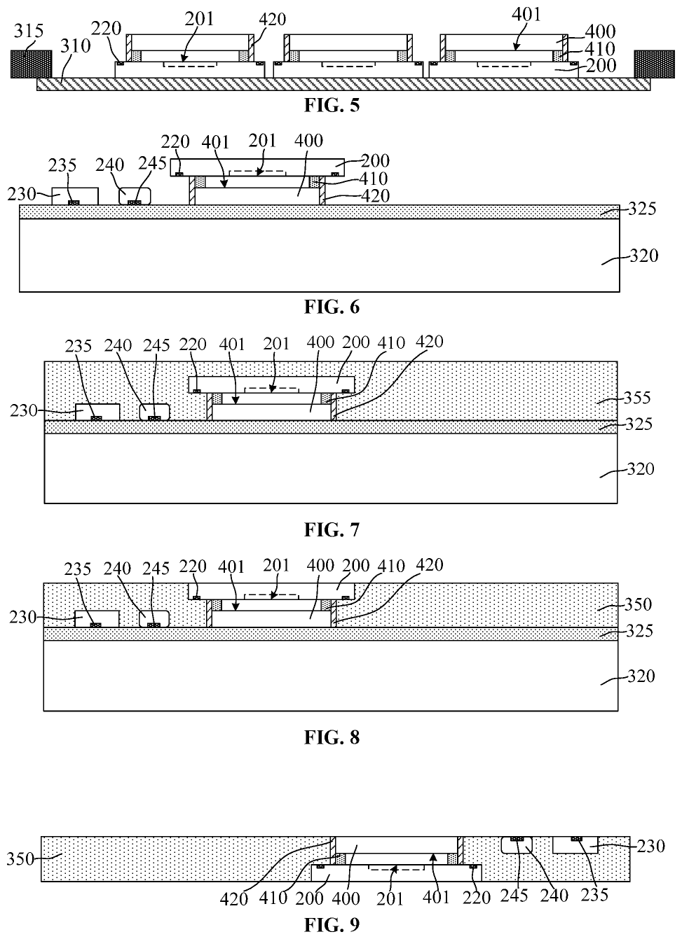

Further, as show in FIG. 5, the packaging method further may also include forming a stress buffer layer 420 to cover the sidewall surfaces of the filter 400.

The stress buffer layer 420 may be beneficial to reduce the stress generated by the subsequent encapsulation layer formed on the filter 400 to reduce the probability of the filter 400 of being broken. Thus, the reliability and the yield of the packaging process may be improved, and the reliability of the lens module may be correspondingly improved. In particular, when the filter 400 is an infrared filter glass sheet or a fully transparent glass sheet, and the glass sheet may be highly susceptible to cracking due to a stress. The stress buffer layer 420 may be able to significantly reduce the cracking probability of the filter 400.

The stress buffer layer 420 may have a certain viscosity to ensure the adhesion on the filter 400. In one embodiment, the material of the stress buffer layer 420 is an epoxy-based glue. Epoxy adhesive is epoxy resin adhesive. Epoxy adhesive may have a variety of forms. By changing the composition, materials with different elastic moduli may be obtained. Accordingly, the stress applied on the filter 400 may be adjusted according to actual conditions.

In one embodiment, the stress buffer layer 420 may also cover the sidewall surfaces of the adhesive structure 410. Thus, the stress generated by the encapsulation layer on the adhesive structure 410 may be reduced, and the reliability and the yield of the packaging process may be further improved.

In one embodiment, after bonding the surface of the photosensitive chip 200 away from the optical signal receiving surface 201 to the UV film 310, the stress buffer layer 420 may be formed by a dispensing process. By selecting the dispensing process, the process for forming the stress buffer layer 420 may be improved in compatibility with the current packaging process, and the process may be substantially simple.

In some embodiments, the stress buffer layer may also be formed before mounting the photosensitive chip and the filter.

Further, as shown in FIG. 6, the packaging method may also include providing a first carrier substrate 320. Functional components (not labeled) and the filter 400 may be temporarily bonded to the first carrier substrate 300. The functional component may have a soldering pad (not labeled). The soldering pad of the functional component may face the first carrier substrate 320.

By temporarily bonding the functional components and the photosensitive chip 200 to the first carrier substrate 320, the process preparation may be completed for the subsequent implementation of the packaging integration and electrical integration of the functional component and the photosensitive chip 200.

Moreover, by the means of the temporary bonding (TB), it may also be convenient to implement the subsequent de-bonding process. The first carrier substrate 320 may also be used to provide a process platform for subsequently forming an encapsulation layer.

In one embodiment, the first carrier substrate 320 is a carrier wafer. In some embodiments, the first carrier substrate may also be other types of substrates.

In particular, the filter 400 and the functional components may be temporarily bonded to the first carrier substrate 320 through a second temporary bonding layer 325. The detailed description of the second temporary bonding layer 325 may refer to the previous description of the first temporary bonding layer 345 (shown in FIG. 1), and the details are not described herein again.

In one embodiment, after temporarily bonding the filter 400 to the first carrier substrate 320, the first soldering pad 220 of the photosensitive chip 200 may face the first carrier wafer 320.

In particular, the UV film 310 (shown in FIG. 5) at the position of a photosensitive unit 250 (shown in FIG. 1) may be irradiated with an ultraviolet light. The UV film 310 irradiated by the ultraviolet light may lose its stickiness, and the photosensitive unit 250 may be lifted up by a protruding tip. Then the photosensitive units 250 may be lifted by a suction device; and sequentially peeled off from the UV film 310 and placed at predetermined positions of the first carrier substrate 320. By placing the photosensitive units 250 one by one on the first carrier substrate 320, the positional accuracy of the photosensitive units 250 on the first carrier substrate 320 may be improved.

In one embodiment, for illustrative purposes, only one photosensitive unit 250 is shown in FIG. 6. In some embodiments, when the formed lens module is applied to a dual camera product or and an array module product, the number of the photosensitive units may be greater than one.

It should be noted that, in one embodiment, after mounting the photosensitive chip 200 and the filter 400, the filter 400 may be temporarily bonded to the first carrier substrate 320. In some embodiments, the photosensitive chip and the filter may also be mounted after the filter is temporarily bonded to the first carrier substrate.

The functional element may be a component having a specific function other than the photosensitive chip 200 in the camera assembly. The functional component may include at least one of a peripheral chip 230 and a passive component 240.

In one embodiment, to reduce the process difficulty during subsequently forming a re-distribution structure, after the functional component is temporarily bonded to the first carrier substrate 320, the soldering pad of the functional component may face the first carrier substrate 320.

When the filter 400 is temporarily bonded to the first carrier substrate 320 and the soldering pad of the functional component faces the first carrier substrate 320, the effect of the thickness difference between the photosensitive chip 200 and the functional component on the formation of the encapsulation layer may be prevented. Accordingly, the process complexity for subsequently forming the encapsulation layer may be reduced.

In one embodiment, the functional component may include a peripheral chip 230 and a passive component 240.

The peripheral chip 230 may be an active component, and may be used to provide peripheral circuits to the photosensitive chip 200 after being electrically connected to the photosensitive chip 200 subsequently. The peripheral circuits may include analog power supply circuits and digital power supply circuits, voltage buffer circuits, shutter circuits, and/or shutter drive circuits, etc.

In one embodiment, the peripheral chip 230 includes at least one of a digital signal processing chip and a memory chip. In some embodiments, chips of other functional types may also be included. Only one peripheral chip 230 is illustrated in FIG. 6, but the number of peripheral chips 230 is not limited to one.

The peripheral chip 230 may be often a silicon-based chip fabricated by the integrated circuit fabrication techniques. The peripheral chip 230 may also have soldering pads for electrically connecting the peripheral chip 230 to other chips or components. In one embodiment, the peripheral chip 230 may have a second soldering pad 235. After the peripheral chip 230 is temporarily bonded to the first carrier substrate 320, the second soldering pad 235 may face the first carrier substrate 320.

The passive component 240 may play a specific role in the photographic operation of the photosensitive chip 200. The passive component 240 may include smaller electronic components such as resistors, capacitors, inductors, diodes, transistors, potentiometers, relays, or drivers, etc. Only one passive component 240 is illustrated in FIG. 6, but the number of passive components 240 is not limited to one.

The passive component 240 may also have soldering pads for electrically connecting the passive component 240 to other chips or components. In one embodiment, the soldering pad of the passive component 240 is an electrode 245. After the passive component 240 is temporarily bonded to the first carrier substrate 320, the electrode 245 may face the first carrier substrate 320.

Further, as shown in FIGS. 7-8, an encapsulation layer 350 (shown in FIG. 8) may be formed. The encapsulation layer 350 may cover the first carrier substrate 320 and functional elements (not labeled), and may cover at least portions of the sidewall surfaces of the photosensitive chip 200.

The encapsulation layer 350 may fix the photosensitive chip 200 and the functional components (for example, the peripheral chip 230 and the passive component 240) to implement a package integration of the photosensitive chip 200 and the functional components.

The encapsulation layer 350 may reduce the spaces occupied by the supports in the lens assembly, and may also allow to omit the circuit board (for example, PCB). Thus, the total thickness of the subsequently formed lens module may be significantly reduced to meet the needs for miniaturization and thinning of the lens module. Moreover, comparing with the solution of mounting the functional elements on the peripheral main board, integrating the photosensitive chip 200 and the functional elements into the encapsulation layer 350 may reduce the distance between the photosensitive chip 200 and each functional element. Accordingly, the electrical connection distance between the photosensitive chip 200 and the functional components may be reduced. Thus, the rate of the signal transmission may be reduced, and the performance of the lens module may be improved. For example, the imaging speed and the storage speed may be increased.

Further, the encapsulation layer 350 may also function as an insulation, sealing and moisture proof. Thus, the reliability of the lens module may be improved.

In one embodiment, the encapsulation layer 350 may be made of epoxy resin. Epoxy resin may have the advantages of low shrinkage, good adhesion, good corrosion resistance, excellent electrical properties and low cost. Thus, epoxy resin is widely used as a packaging material for electronic devices and integrated circuits.

In particular, the encapsulation layer 350 may be formed by an inject molding process. The inject molding process may have the characteristics of high production speed, high efficiency, and automation of operation. Thus, the production quantity may be increased and the process cost may be reduced. In some embodiments, the encapsulation layer may also be formed by other molding processes.

In one embodiment, the process for forming the encapsulation layer 350 may include forming an encapsulation material layer 355 (as shown in FIG. 7) to cover the first carrier substrate 320, the functional components and the photosensitive chip 200; and performing a grinding process to the encapsulation material layer 355 to form the encapsulation layer 350. The top surface of the encapsulation layer 350 may level with the highest one of the photosensitive chips 250 and functional elements.

By the grinding process, the thickness of the encapsulation layer 350 may be reduced. Thus, the total thickness of the formed lens module may be reduced.

Because the filter 400 may be temporarily bonded to the first carrier substrate 320, during the process for forming the encapsulation material layer 355, it may not be necessary to customize the mold required for the inject molding process. Accordingly, the process may be simplified.

In one embodiment, the total thickness of the photosensitive unit 250 may be greater than the thickness of the functional elements. Thus, after the grinding process, the surface of the encapsulation layer 350 facing away from the first carrier substrate 320 may level with the surface of the photosensitive chip 200 facing away from the carrier substrate 320. In particular, the encapsulation layer 350 may cover the sidewall surfaces of the photosensitive chip 200.

In one embodiment, the encapsulation layer 350 may also cover the sidewall surfaces of the filter 400. Thus, the sealing property of the cavity in the photosensitive unit 250 may be improved, and the probability for water vapor, oxidizing gas, etc. to enter the cavity may be reduced. Accordingly, the performance of the photosensitive chip 200 may be ensured.

It should be noted that, under the action of the encapsulation layer 350, the circuit board is omitted, and the thickness of the lens module may be reduced. Thus, the photosensitive chip 200 and the peripheral chip 230 may not need to be thinned. Accordingly, the mechanical strength and reliability of the photosensitive chip 200 and the peripheral chip 230 may be improved. In some embodiments, the thickness of the photosensitive chip and the peripheral chip may be appropriately reduced according to process requirements, but the amount of thinning may be substantially small to ensure that the mechanical strength and reliability are not affected.

Further, as shown in FIG. 9, a second de-bonding process may be performed to remove the first carrier substrate 320 (as shown in FIG. 8).

By removing the first carrier substrate 320, the soldering pads of the functional components may be exposed. Thus, a process base for the subsequent electrical connection process may be prepared.

In one embodiment, the second de-bonding process may include sequentially removing the first carrier substrate 320 and the second temporary bonding layer 325 (as shown in FIG. 8). The detailed description of the second de-bonding process may refer to the previous description of the first de-bonding process, and details are not described herein again.

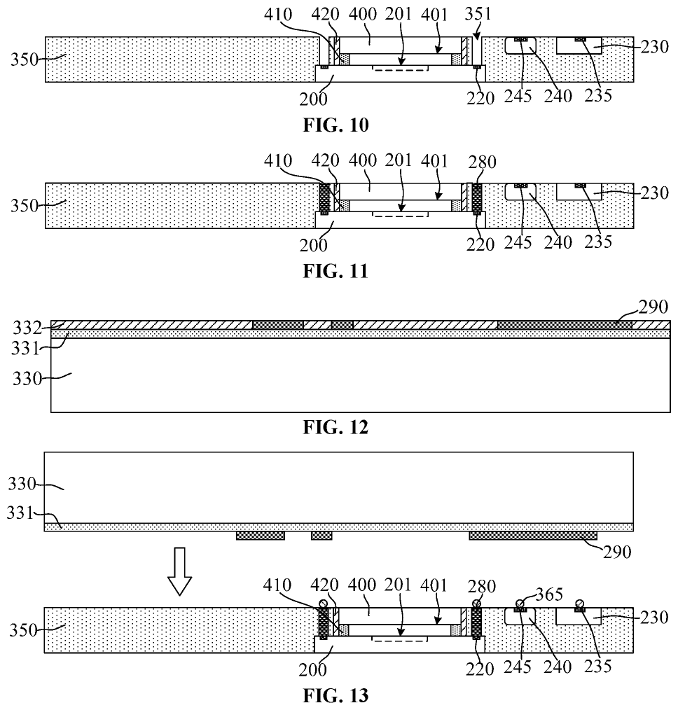

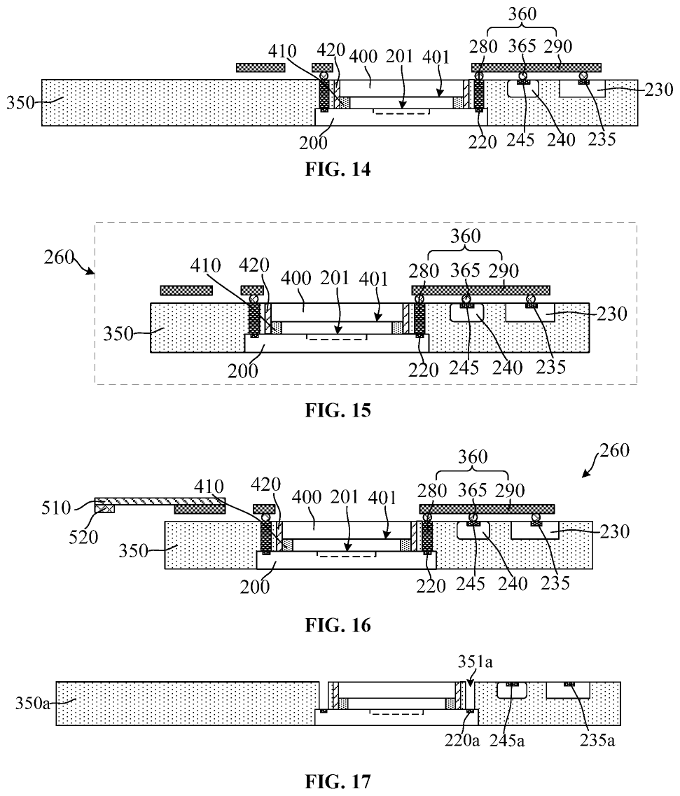

Further, referring to FIG. 10 to FIG. 14, after removing the first carrier substrate 320, a re-distribution layer (RDL) structure 360 may be formed on a side of the package layer 350 adjacent to the filter 400 (as shown in FIG. 14). The soldering pad of the photosensitive chip 200 and the soldering pads (not labeled) of the functional components (not labeled) may be electrically connected.

The re-distribution layer structure 360 may be used to implement an electrical integration of the formed camera assembly. By using the encapsulation layer 350 and the re-distribution layer structure 360, the distance between the photosensitive chip 200 and the functional components may be reduced. Accordingly, the electrical connection distance between the photosensitive chip 200 and the functional components may be reduced. Thus, the speed of signal transmission may be increased, and the performance of the lens module may be enhanced. In particular, the peripheral chip 230 may include one or both of a digital signal processor chip and a memory chip, the photographing speed and the storage speed may be correspondingly improved.

Moreover, by selecting the re-distribution layer structure 360, it is possible to improve the feasibility of the electrical connection process while reducing the distance between the photosensitive chip 200 and the functional elements. Further, comparing with the wire bonding process, the re-distribution layer structure 360 may realize batch processing. Thus, the packaging efficiency may be improved.

In addition, the re-distribution layer structure 360 may be formed on a side of the encapsulation layer 350 adjacent to the filter 400. After the lens assembly is subsequently assembled on the encapsulation layer 350, the re-distribution layer structure 360 may be correspondingly disposed on the support of the lens assembly. Thus, the re-distribution layer structure 360 may be protected. Accordingly, the reliability and the stability of the lens module may be improved, and it may facilitate the subsequent packaging of the lens module.

In one embodiment, the re-distribution layer structure 360 may electrically connect the first soldering pad 220, the second soldering pad 235, and the electrode 245. The second soldering pad 235 and the electrode 245 may be exposed by the encapsulation layer 350. Thus, the process for forming the re-distribution layer structure 360 may be substantially simple.

In particular, the process for forming the re-distribution layer structure 360 may include following steps.

As shown in FIGS. 10-11, a conductive plug 280 (as shown in FIG. 11) may be formed in the encapsulation layer 350. The conductive plug 280 may be electrically connected to the soldering pad of the photosensitive chip 200.

The conductive plug 280 may be electrically connected to the first soldering pad 220 to be used as an external electrode of the photosensitive chip 200. The photosensitive chip 200 may be subsequently electrically connected to the functional component through the conductive plug 280. The conductive plug 280 may be electrically connected to the metal interconnect structure in the photosensitive chip 200. In some embodiments, the conductive plug 280 may pass through the photosensitive chip 200 and may be directly connected to the first soldering pad 220.

The top surface of the conductive plug 280 may be exposed by the encapsulation layer 350. Through the conductive plug 280, the external electrode of the photosensitive chip 200 and the soldering pad of the functional component may be disposed at a same side of the encapsulation layer 350. Thus, the process difficulty for forming the re-distribution layer structure 360 may be reduced. The top surface of the conductive plug 280 may be referred to the surface of the conductive plug 280 facing away from the surface of the photosensitive chip 200 along the extending direction (length direction) of the conductive plug 280.

In one embodiment, the conductive plug 280 may be made of copper. Thus, the conductive performance of the conductive plug 280 may be improved, and the process difficulty for forming the conductive plug 280 may be reduced. In some embodiments, the conductive plug may also be made of other appropriate conductive material, such as tungsten, etc.

In particular, the process for forming the conductive plug 280 may include patterning the encapsulation layer 350 to form a conductive via 351 (as shown in FIG. 10) exposing the first soldering pad 220 in the encapsulation layer 350; and forming the conductive plug 280 in the conductive via 351.

In one embodiment, the conductive via 351 may be formed by an etching process. In particular, the encapsulation layer 350 may be etched by a laser etching process to form the conductive via 351. The precision of the laser etching process may be substantially high, and the position and size of the conductive via 351 may be determined with a substantially high accuracy.

In one embodiment, the conductive plug 280 is formed in the conductive via 351 by an electroplating process.

Comparing with the scheme of bonding the conductive plug into the conductive via, the present embodiment may form the conductive plug 280 in the conductive via 351 by filling the conductive via 351, the process difficulty of forming the conductive plug 280 may be reduced. Further, the alignment issue may be avoided and the reliability of the electrical connection between the conductive plug 280 and the first soldering pad 220 may be improved.

Referring to FIGS. 12-14, an interconnect wiring 290 may be formed on a side of the encapsulation layer 350 adjacent to the filter 400; and the conductive plug 280 may be electrically connected to the soldering pad of the functional element.

In one embodiment, the process for forming the interconnect wiring 290 may include following steps

As shown in FIG. 12, a second carrier substrate 330 may be provided, and the interconnection wiring 290 may be formed on the second carrier substrate 330.

In particular, a third temporary bonding layer 331 may be formed on the second carrier substrate 330; a first dielectric layer 332 may be formed on the third temporary bonding layer 331; the first dielectric layer 332 may be patterned to form a first interconnect trench (not labeled) in the first dielectric layer 332; and the interconnect wiring 290 may be formed in the first interconnect trench.

In one embodiment, the interconnect wiring 290 may be filled in the first interconnect trench. Correspondingly, the process complexity for forming the interconnect wiring 290 may be reduced.

The third temporary bonding layer 331 may be used as a peeling layer to facilitate the subsequent separation of the interconnecting wiring 290 from the second carrier substrate 330. In one embodiment, the third temporary bonding layer 331 may be a foamed film. The detailed description of the third temporary bonding layer 331 may refer to the second temporary bonding layer 345 (as shown in FIG. 1), and the corresponding description is not repeated herein.

The first interconnect trench formed in the first dielectric layer 332 may be used to define the shape, location, and size of the interconnect wiring 290. In one embodiment, the material of the first dielectric layer 332 is a photosensitive material, and correspondingly may be patterned by a photolithography process. In particular, the material of the first dielectric layer 332 may be photosensitive polyimide, photosensitive benzocyclobutene, or photosensitive polybenzoxazole, etc.

The first dielectric layer 332 made of such materials may have a substantially high corrosion resistance. Thus, after forming the interconnection wiring 290, the first dielectric layer 332 may be removed by a reactive ion etching process; and a process foundation for subsequently performing an electrical connection process may be provided.

It should be noted that, in some embodiments, before forming the third temporary bonding layer on the second carrier substrate, a passivation layer may be formed on the second carrier substrate. The passivation layer may prevent the second carrier substrate from being contaminated such that the second carrier substrate may be reused. In one embodiment, the passivation layer may be made of silicon oxide, or silicon nitride, etc.

It should also be noted that, in other embodiments, when the interconnect wiring is made of a material (for example, aluminum) that is easily patterned by an etching process, the interconnect wiring may be formed by the etching process. Correspondingly, the process for forming the interconnect wiring may include forming a conductive layer on the third temporary bonding layer; and etching the conductive layer to form the interconnect wiring.

As shown in FIG. 13 and FIG. 14, in one embodiment, the process for forming the re-distribution layer structure 360 (shown in FIG. 14) may further include forming a conductive bump 365 on the conductive plug 280 and the soldering pad of the functional component. The interconnecting wiring 290 may be bonded to the conductive bump 365 and electrically connected to the conductive bump 365.

The conductive bump 365 may protrude from the conductive plug 280, the second soldering pad 235 and the electrode 245. Through the conductive bump 365, the reliability of the bonding between the interconnect wiring 290 and the conductive plug 280, and the bonding between the second soldering pad 235 and the electrode 245 may be improved.

Moreover, by forming the conductive bumps 365 on the conductive plug 280, the second soldering pad 235 and the electrode 245, the positional accuracy of the conductive bumps 365 may be improved, and the process difficulty for forming the conductive bumps 365 may be reduced.

In one embodiment, the conductive bumps 365 are formed by a reballing process. By selecting the reballing process, the reliability of the signal transmission between the chips and components and the re-distribution layer structure 360 may be improved. In particular, the conductive bumps 365 may be made of tin.

In one embodiment, the interconnect wiring 290 may be bonded to the conductive bumps 365 by a metal bonding process.

In particular, the metal bonding process is a thermo-compression bonding process. During the metal bonding process, the contact faces of the interconnect 290 and the conductive bump 365 may be plastically deformed under a pressure such that the atoms of the contact surfaces contact with each other. Further, as the bonding temperature increases, the atomic diffusion of the contact surfaces may be accelerated to achieve a transboundary diffusion. When a certain bonding time is reached, the lattices of the contact surfaces may be recombined to form a bonding structure. The bonding strength, electrical and thermal conductivity, electro-migration resistance, and mechanical connection of the bonding structure may be substantially high.

It should be noted that, as the bonding temperature increases, the atoms on the contact surfaces may obtain more energy, and the diffusion among atoms may be more obvious. The increase of the bonding temperature may also promote the crystal grain growth. The crystal grains obtaining the energy may cross the interface and may facilitate to eliminate the interface and may cause the materials of the contact surfaces to mingle together. However, if the bonding temperature is too high, it is easy to adversely affect the performance of the photosensitive chip 200 and the peripheral chip 230, especially for the sensitive components in the formed camera assembly. Further, if the bonding temperature is too high, a thermal stress may be generated, problems such as decreased alignment accuracy, increased process cost, and reduced production efficiency may be caused. Thus, in one embodiment, the metal bonding process may be a low temperature metal bonding process, and the bonding temperature of the metal bonding process may be equal to or less than approximately 250° C., as long as the lowest value of the bonding temperature is sufficient to achieve the bonding.

When the bonding temperature is set at the appropriate value, by increasing the pressure, the inter-diffusion of atoms of the contact surfaces may be easier. Accordingly, the bonding quality between the interconnect wiring 290 and the conductive bump 365 may be improved. Thus, in one embodiment, the pressure of the metal bonding process may be greater than or equal to approximately 200 kPa. The pressure may be generated by a pressing tool.

Further, increasing the bonding time may also improve the bonding quality. Thus, in one embodiment, the bonding time of the metal bonding process may be greater than or equal to approximately 30 mins.

It should be noted that, in the practical process, the bonding temperature, the bonding pressure and the bonding time may be reasonably adjusted and matched to each other to ensure the quality and the efficiency of the metal bonding process. It should also be noted that, to reduce the probability of oxidation or contamination of the contact surfaces, the metal bonding process may be performed in a vacuum environment.

It also should be noted that, in some embodiments, after forming the interconnect wiring on the second carrier substrate, the conductive bumps may also be formed on the interconnect wiring. Correspondingly, the conductive bumps may be bonded to the corresponding conductive plug and the soldering pad of the functional components by the metal bonding process. The conductive pug, the conductive bumps and the interconnect wiring may form a re-distribution layer structure.

In one embodiment, the process for forming the conductive bumps on the interconnect wiring may include forming a second dielectric layer covering the second carrier substrate and the interconnect wiring; patterning the second dielectric layer to form an interconnect via in the second dielectric layer to expose a portion of the interconnect wiring; forming the conductive bump in the interconnect via by an electroplating process; and removing the second dielectric layer.

Correspondingly, the material of the conductive bumps may also be the same as the material of the conductive plug and the interconnect wiring.

After forming the conductive bumps, the second dielectric layer may be removed by a reactive ion etching process.

The detailed description of the second dielectric layer may refer to the corresponding description of the first dielectric layer, and details are not described herein again.

In one embodiment, after forming the re-distribution layer structure 360, a third de-bonding process may be performed to remove the second carrier substrate 330 and the third temporary bonding layer 331. The detailed description of the third de-bonding process may refer to the previous description of the first de-bonding process, and details are not described herein again.

Further, as shown in FIG. 15, after the third de-bonding process, the packaging process may further include performing a dicing process on the encapsulation layer 350.

Through the dicing process, an individual camera assembly 260 with a size meeting the process requirements may be formed; and the process base for the subsequent assembly of the lens module may be prepared. In one embodiment, the dicing process may be performed using a laser cutting method.

Further, as shown in FIG. 16, after forming the re-distribution layer structure 360, the packaging method may further include bonding a flexible printed circuit (FPC) board 510 on the re-distribution layer structure 360.

The FPC board 510 may be configured to implement an electrical connection between the camera assembly 260 and the subsequently formed lens module and an electrical connection between the formed lens module and other components in the case when an circuit board is omitted. After subsequently forming the lens module, the lens module may also be electrically connected to other components in the electronic device through the FPC board 510. Thus, a normal imaging function of the electronic device may be realized.

In one embodiment, the FPC board 510 may contain circuit structures. Therefore, the FPC board 510 may be bonded to the re-distribution layer structure 360 by a metal bonding process to form electrical connections. In particular, the FPC board 510 may be bonded to the interconnect wiring 290.

In one embodiment, to improve the process feasibility, the FPC board 510 may be bonded on the re-distribution layer structure 360 after the third de-bonding process and the dicing process.

It should be noted that, a connector 520 may be formed on the FPC board 510 for electrically connecting the FPC board 510 to other circuit components. When the lens module is used in the electronic device, the connector 520 may be electrically connected to the main board of the electronic device. Thus, the information transmission between the lens module and other components in the electronic device may be realized, and the image information of the lens module may be transmitted to the electronic device. In particular, the connector 520 may be a gold finger connector.

FIGS. 17-20 illustrate structures corresponding to certain steps of during another exemplary packaging method of a camera assembly consistent with various disclosed embodiments.

The details similar to the previous embodiments are not described herein again. Comparing with previous embodiments, the major difference may include that, during the process for forming a re-distribution layer structure 360a, the conductive plug 280a and the interconnect wiring 290a may be formed in a same step.

In particular, as shown in FIG. 17, the encapsulation layer 250a may be patterned, and a conductive via 351a exposing the first soldering pad 220a may be formed in the encapsulation layer 250a.

In one embodiment, the conductive via 351a may be formed by a laser etching process. The detailed description of the steps for forming the conductive via 351a may be referred to the corresponding description in the previous embodiments, and details are not described herein again.

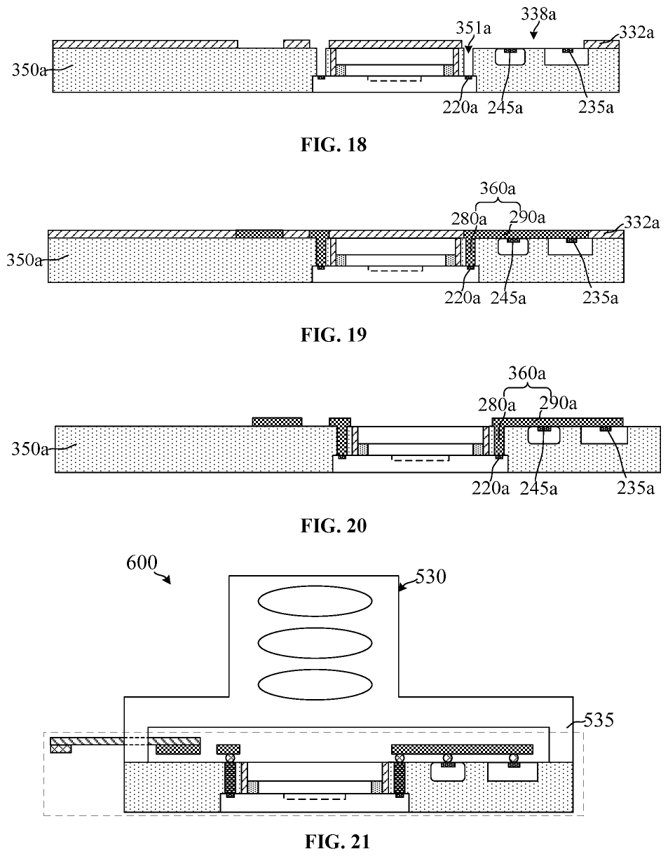

Further, as shown in FIG. 18, a third dielectric layer 332a covering the encapsulation layer 350a, a filter (not labeled), and a functional component (not labeled) may be formed; and the third dielectric layer 332a may also be formed in the conductive via 351a. Then, the third dielectric layer 332a may be patterned by removing the portion of the third dielectric layer 332a in the conductive via 351a and the portion of the third dielectric layer 332a above the top of the encapsulation layer 350a to form a second interconnect trench 338a in the third dielectric layer 332a. The interconnect trench 338a may expose the second soldering pad 235a and the electrode 245a, and the second interconnect trench 338a may connect with the conductive via 351a.

The detailed description of the third dielectric layer 332a may refer to the corresponding description of the first dielectric layer in the previous embodiments, and details are not described herein again.

Further, as shown in FIG. 19, a conductive material may be filled into the second interconnect trench 338a (shown in FIG. 18) and the conductive via 351a (shown in FIG. 18), and a conductive plug 280a may be formed in the conductive via 351a. Further, an interconnect wiring 290a may be formed in the second interconnect trench 338a. The interconnect line 290a and the conductive plug 280a may form an unitary re-distribution layer structure 360a.

In one embodiment, the conductive plug 280a may be formed in the conductive via 351a by an electroplating process, and the interconnect wiring 290a may be formed in the second interconnect trench 338a by the electroplating process.

Further, as shown in FIG. 20, the third dielectric layer 332a may be removed (as shown in FIG. 19).

In one embodiment, the third dielectric layer 332a may be removed by a reactive ion etching process.

The detailed description of the packaging method may be referred to the corresponding description in the previous embodiments, and details are not described herein again.

The present disclosure also provides a camera assembly. FIG. 16 illustrates an exemplary camera assembly consistent with various disclosed embodiments.

As shown in FIG. 16, the camera assembly 260 may include an encapsulation layer 350, and a photosensitive unit 250 (as shown in FIG. 1) and functional elements (not labeled) embedded in the encapsulation layer 350. The photosensitive unit 250 may include a photosensitive chip 200 and a filter 400 mounted on the photosensitive chip 200. The top surface of the encapsulation layer 350 may expose the filter 400 and the functional elements. The bottom surface of the encapsulation layer 350 may be higher than the functional elements, and the encapsulation layer 350 may cover at least portions of the sidewall surfaces of the photosensitive chip 200. The photosensitive chip 200 and the functional elements may all contain soldering pads. The soldering pad of the photosensitive chip 200 may face the top surface of the encapsulation layer 350. The soldering pads of the functional components may be exposed on the top surface of the encapsulation layer 350. The camera assembly may also include a re-distribution layer structure 360. The re-distribution layer structure 360 may be disposed at a side of the encapsulation layer 350 adjacent to the filter 400, and the re-distribution layer structure 360 may electrically connect the soldering pads.

The encapsulation layer 350 may fix the photosensitive chip 200 and the functional elements for implementing the packaging integration of the photosensitive chip 200 and the functional elements. Further, the encapsulation layer 350 may reduce the space occupied by the support in the lens assembly, and also allow to omit the circuit board. Thus, the thickness of the lens module may be reduced, and the requirements of miniaturization and thinning of the lens module may be met.

The material of the encapsulation layer 350 may be a plastic encapsulation material, and the encapsulation layer 350 may also be able to function as an insulation, sealing and moisture proof layer. Thus, the encapsulation layer 350 may improve the reliability of the lens module. In one embodiment, the encapsulation layer 350 is made of an epoxy resin.

In one embodiment, the encapsulation layer 350 may include a top surface and an opposing bottom surface. The top surface of the encapsulation layer 350 may be referred to as the surface for mounting the lens assembly.

In one embodiment, the bottom surface of the encapsulation layer 350 may level with the highest one of the photosensitive unit 250 and the functional elements. Correspondingly, the effect of the formation process of the encapsulation layer 350 on the thickness difference between the photosensitive chip 200 and the functional components may avoided. During the process for forming the encapsulation layer 350, a customized mold may not be required, and the fabrication process may be simplified.

In one embodiment, the total thickness of the photosensitive unit 250 may be greater than the thickness of the functional components. Thus, the bottom surface of the encapsulation layer 350 and the surface of the photosensitive chip 200 opposing to the filter 400 may level with each other. That is, the encapsulation layer 350 may cover the sidewall surfaces of the photosensitive chip 200.

The encapsulation layer 350 may also cover the sidewall surfaces of the filter 400. Thus, the sealing property of the cavity in the photosensitive unit 250 may be improved; and the probability for water vapor, and/or oxidizing gas, etc., entering the cavity may be reduced. Accordingly, the performance of the photosensitive chip 200 may be ensured.

The photosensitive chip 200 may be an imaging sensor chip. In one embodiment, the photosensitive chip 200 is a CMOS imaging sensor chip. In some embodiments, the photosensitive chip may also be a CCD imaging sensor chip.

In one embodiment, the photosensitive chip 200 may include a photosensitive region 200C (as shown in FIG. 2) and a peripheral region 200E (as shown in FIG. 2) surrounding the photosensitive region 200C. The photosensitive chip 200 may also have an optical signal receiving surface 201 disposed in the photosensitive region 200C.

The photosensitive chip 200 may typically be a silicon-based chip, and the soldering pads of the photosensitive chip 200 may be used to electrically connect the photosensitive chip 200 with other chips or components. In one embodiment, the photosensitive chip 200 may have a soldering pad 220 located in the peripheral region 200E, and the first soldering pad 220 may face the top surface of the encapsulation layer 350.

The filter 400 may be mounted on the photosensitive chip 200 to prevent contamination of the optical signal receiving surface 201 caused by the packaging process. Further, the overall thickness of the lens module may be reduced, and the requirements of miniaturization and thinning of the lens module may be met.

To achieve the normal function of the lens module, the filter 400 may be an infrared filter glass sheet or a fully transparent glass sheet. In one embodiment, the filter 400 is an infrared filter glass sheet, and may be used to eliminate the influence of infrared light in the incident light on the performance of the photosensitive chip 200. Accordingly, the imaging performance may be improved.

In one embodiment, the filter 400 is mounted on the photosensitive chip 200 by using a bonding structure 410, and the bonding structure 410 may surround the optical signal receiving surface 201. The bonding structure 410 may be used to implement an physical connection between the filter 400 and the photosensitive chip 200. The filter 400 may not directly contact with the photosensitive chip 200. Thus, an adverse effect on the optical performance of the photosensitive chip 200 may be avoided.

In one embodiment, the material of the bonding structure 410 is a photolithographic dry film. In some embodiments, the material of the bonding structure may also be a photolithographic polyimide, a photolithographic polybenzoxazole, or a photolithographic benzocyclobutene, etc.

In one embodiment, the bonding structure 410 may surround the optical signal receiving surface 201 such that the filter 400 above the optical signal receiving surface 201 may be disposed in the photo-sensing path of the photosensitive chip 200. Thus, the performance of the photosensitive chip 200 may be ensured.

It should be noted that, for illustrative purposes, only one photosensitive unit 250 is described. In some embodiments, when the lens module is used in a dual-camera or an array module product, the number of photosensitive chips may be greater than one.

It should be noted that, because the encapsulation layer 350 may cover the sidewall surfaces of the filter 400, the camera assembly 260 may also include a stress buffer layer 420 between the encapsulation layer 350 and the sidewall surfaces of the filter 400. The stress buffer layer 420 may be beneficial to reduce the stress generated by the encapsulation layer 350 on the filter 400 to reduce the probability of the filter 400 being broken. Thus, the reliability of the lens module may be improved.

In one embodiment, the stress buffer layer 420 may be made of an epoxy-based glue.

In one embodiment, the stress buffer layer 420 may also be disposed between the encapsulation layer 350 and the sidewall surfaces of the bonding structure 410 to reduce the stress generated by the encapsulation layer 350 on the bonding structure 410. Thus, the reliability and the yield of the camera assembly 260 may be further improved.

The functional components may be components having specific functions other than the photosensitive chip 200 in the camera assembly, and may include at least one of a peripheral chip 230 and a passive component 240.

In one embodiment, the functional elements may include a peripheral chip 230 and a passive component 240.

In one embodiment, the soldering pads of the functional elements may be exposed on the top surface of the encapsulation layer 350. Thus, the process complexity for forming the interconnect structure 360 may be improved.

The peripheral chip 230 may be an active component for providing peripheral circuits to the photosensitive chip 200, such as an analog power supply circuit and a digital power supply circuit, a voltage buffer circuit, a shutter circuit, and/or a shutter drive circuit, etc.

In one embodiment, the peripheral chip 230 may include one or two of a digital signal processor chip and a memory chip. In some embodiments, the peripheral chip may also include chips of other functional types. Only one peripheral chip 230 is illustrated in FIG. 16, but the number of the peripheral chips is not limited to one.

The peripheral chip 230 may typically be a silicon-based chip, and the soldering pads of the peripheral chip 230 may be used to electrically connect the peripheral chip 230 with other chips or components. In one embodiment, the peripheral chip 230 includes a second soldering pad 235; and the second soldering pad 235 may be exposed on the top surface of the encapsulation layer 350.

The re-distribution (wiring) structure 360 may be used to implement electrical integration of the camera assembly. By using the re-distribution layer structure 360 and the encapsulation layer 350, the performance of the lens module may be improved (for example, the imaging speed and the storage speed may be improved). Moreover, the feasibility of the electrical connection process and the packaging efficiency are improved by using the re-distribution layer structure 360.

Further, the re-distribution layer structure 360 may be disposed at a side of the encapsulation layer 350 adjacent to the filter 400. After the lens assembly is assembled to the top surface of the encapsulation layer 350, the re-distribution layer structure 360 may be correspondingly located in the support of the lens assembly. Thus, the reliability and stability of the lens module may be improved, and the subsequent packaging of the lens module may be facilitated.

In one embodiment, the re-distribution layer structure 360 may electrically connects the first soldering pad 220, the second soldering pad 235, and the electrode 245.

The first soldering pad 220 of the photosensitive chip 200 may face the filter 400. In particular, the first soldering pad 220 may face the top surface of the encapsulation layer 350, and the second soldering pad 235 and the electrode 245 may be exposed on the top surface of the encapsulation layer 350. The re-distribution layer structure 360 may include a conductive plug 280 disposed in the encapsulation layer 350 and electrically connected to the first soldering pad 220; and an interconnect wiring 290 disposed on the second soldering pad 235, the electrode 245 and the conductive plug 280. The interconnect wiring 290 may electrically connect the second soldering pad 235, the electrode 245, and the conductive plug 280.

The conductive plug 280 may be electrically connected to the first soldering pad 220 to be used as an external electrode of the photosensitive chip 200. Such a configuration may allow the external electrode of the photosensitive chip 200, the second soldering pad 235 and the electrode 245 to be disposed at the same side of the encapsulation layer 350 to form electrical connections among the photosensitive chip 200, the peripheral chip 230, and the passive component 240. The conductive plug 280 may be electrically connected to the metal interconnect structure in the photosensitive chip 200. In some embodiments, the conductive plug may pass through the photosensitive chip and be directly connected to the first soldering pad.

In one embodiment, the conductive plug 280 and the interconnect wiring 290 may be both made of copper. By using copper, the electrical connection reliability and conductivity of the re-distribution layer structure 360 may be improved. Further, the process difficulty for forming the conductive plug 280 and the interconnect wiring 290 may be reduced. In some embodiments, the conductive plug and the interconnect wiring may be made of other appropriate conductive materials.

In one embodiment, the conductive plug 280 and the interconnect wiring 290 may be respectively formed in different fabrication steps. Thus, the interconnect wiring 290 and the conductive plug 280, and the second soldering pad 235 and the electrode 245 may be bonded by metal bonding processes.

In one embodiment, the re-distribution layer structure 360 may also include conductive bumps 365 between the interconnect wiring 290 and the second soldering pad 235, and between the electrode 245 and the conductive plug 280, respectively. The conductive bumps 365 may protrude from the conductive plug 280, the second soldering pad 235, and the electrode 245 to improve the bonding reliability between the interconnect wiring 290 and the conductive plug 280, and between the second soldering pad 235 and the electrode 245.

In one embodiment, the conductive bump 365 may be a soldering ball formed by a reballing process. By using the reballing process, the reliability of signal transmission between each chip and component and the re-distribution layer structure 360 may be improved. In particular, the conductive bumps 365 may be made of tin. In some embodiments, the material of the conductive bumps may be the same as the material of the interconnect wiring.

In one embodiment, the camera assembly 260 may also include an FPC board 510 disposed on the re-distribution layer structure 360. The FPC board 510 may be used to form an electrical connection between the camera assembly 260 and the lens assembly and an electrical connection between the lens module and other components in the case when the circuit board is omitted. The lens module may also pass through the FPC board 510 to electrically connect to other components in the electronic device to implement a normal imaging function of the electronic device.

In particular, the FPC board 510 may be bonded to the interconnect wiring 290. The FPC board 510 may contain circuit structures thereon to form an electrical connection between the FPC board 510 and the re-distribution layer structure 360.

It should be noted that the FPC board 510 may contain a connector 520. When the lens module is applied to the electronic device, the connector 520 may be electrically connected to the main board of the electronic device to realize information transmission between the lens module and other components in the electronic device. Accordingly, the image information obtained by the lens module may be transmitted to the electronic device. In embodiment, the connector 520 may be a gold finger connector.

The camera assembly may be formed by using the previously described packaging method, or may be packaged by other packaging methods. The detailed description of the camera assembly may be referred to the previous description, and details are not described herein again.

FIG. 20 illustrates another exemplary camera assembly consistent with various disclosed embodiments.

The details similar to the previous embodiments are not described herein again. Comparing with the previous embodiments, the major difference may include that the re-distribution layer structure 360a may include only the conductive plug 280a and the interconnect wiring 290a.

The camera assembly may be formed by using the packaging method described in the previous embodiments, or may be formed by other packaging methods. The detailed description of the camera assembly may be referred to the previous embodiments, and details are not described herein again.

Further, the present disclosure provides a lens module. FIG. 21 illustrates an exemplary lens module consistent with various disclosed embodiments.

As shown in FIG. 21, the lens module 600 may include an disclosed camera assembly (as shown by a broken line in FIG. 21); and a lens assembly 530. The lens assembly may include a support 535. The support 535 may be mounted on the top surface of the encapsulation layer (not labeled); and may surround the photosensitive unit (not labeled) and functional elements (not labeled). The lens assembly 530 may be electrically connected to the photosensitive chip and the functional elements.

The lens assembly 530 may often include a support 535, a motor (not shown) mounted on the support 535, and a lens group (not labeled) mounted on the motor. By using the support 535, the assembly of the lens assembly 530 may be easily performed; and the lens group may be disposed on the photo-sensing path of the photosensitive unit.

In one embodiment, the thickness of the camera assembly may be substantially small. By using the encapsulation layer, the thickness of the lens assembly 530 may be reduced. Accordingly, the total thickness of the lens module 600 may be reduced.

Moreover, the photosensitive unit and functional elements (for example, peripheral chips) may be disposed inside the support 535. Comparing to the scheme of mounting the functional components on the peripheral motherboard, such a configuration may reduce the size of the lens module 600; and the distance of the electrical connection may be reduced. Accordingly, the signal transmission speed of the lens module 600 may be increased; and the performance of the lens module 600 may be enhanced. For example, the imaging speed and the storage speed may be increased.

Further, the photosensitive unit and the functional components may be integrated in the encapsulation layer, and the photosensitive unit, the functional components and the re-distribution layer structure may all be disposed inside the support 535. Thus, the photosensitive unit, the functional components and the re-distribution layer structure may all be protected. Accordingly, the reliability and stability of the lens module 600 may be improved, and the imaging quality of the lens module 600 may be ensured.

In one embodiment, an FPC board (not labeled) may be bonded to the re-distribution layer structure, and the motor in the lens assembly 530 may be electrically connected to the chips and components in the camera assembly through the FPC board.

The detailed description of the camera assembly may be referred to the description of the previous embodiments, and details are not described herein again.

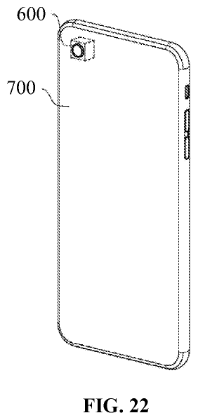

Further, the present disclosure also provides an electronic device. FIG. 22 illustrates an exemplary electronic device consistent with various disclosed embodiments.

As shown in FIG. 22, the electronic device 700 may include a disclosed lens module 600.

The reliability and performance of the lens module 600 may be substantially high, and the imaging quality, imaging speed, and the storage speed of the electronic device 700 may be correspondingly improved. Further, the overall thickness of the lens module 600 may be substantially small. Thus, the user experience may be improved.

In particular, the electronic device 700 may be various devices having a photographing function, such as a mobile phone, a tablet computer, a camera, or a video camera, etc.

Comparing with the prior art, the technical solution of the present disclosure may have the following advantages.

In the present disclosure, the photosensitive chip and the functional components may be integrated in the encapsulation layer, and the electrical connections may be realized through the re-distribution layer structure. Comparing with the scheme of mounting the functional device on the peripheral mainboard, the embodiments of the present disclosure may reduce the distance between the photosensitive chip and the functional components. Correspondingly, the electrical connection distance between the photosensitive chip and the functional components may be reduced. Thus, the speed of signal transmission may be significantly increased. Accordingly, the performance of the lens module may be significantly improved (for example, the imaging speed and storage speed may be increased). Moreover, through the encapsulation layer and the re-distribution layer structure, the circuit board (for example, PCB) may be omitted. Thus, the total thickness of the lens module may be reduced; and the requirements of the miniaturization and the thinning of the lens module may be satisfied.

Although the present disclosure has been disclosed above, the present disclosure is not limited thereto. Any changes and modifications may be made by those skilled in the art without departing from the spirit and scope of the disclosure, and the scope of the disclosure should be determined by the scope of the claims.

What is claimed is:

1. A method for packaging a camera assembly, comprising:
providing a filter and a photosensitive chip having a soldering pad;
mounting the filter to the photosensitive chip with the filter facing the soldering pad of the photosensitive chip;
providing a first carrier substrate and temporarily bonding functional components and the filter on the first carrier substrate, wherein the functional components contain soldering pads facing the first carrier substrate;
forming an encapsulation layer to cover the first carrier substrate and the functional components, and at least cover portions of sidewall surfaces of the photosensitive chip;
removing the first carrier substrate; and
forming a re-distribution layer structure on a side of the encapsulation layer adjacent to the filter to electrically connect the soldering pad of the photosensitive chip and the soldering pads of the functional components.

2. The method according to claim 1, wherein forming the re-distribution layer structure comprises:
forming a conductive plug electrically connected to the soldering pad of the photosensitive chip in the encapsulation layer; and
forming an interconnect wiring on a side of the encapsulation layer adjacent to the filter to electrically connect the conductive plug and the soldering pads of the functional components.

3. The method according to claim 2, wherein forming the conductive plug comprises:
patterning the encapsulation layer to form a conductive via exposing the soldering pad of the photosensitive chip in the encapsulation layer; and
forming the conducive plug in the conductive via.

4. The method according to claim 2, wherein forming the interconnect wiring comprises:
providing a second carrier wafer and forming the interconnect wiring on the second carrier wafer,
wherein forming the re-distribution layer structure further comprises forming conductive bumps on the conductive plug and the soldering pads of the functional components and bonding the interconnect wiring on the conductive bumps.

5. The method according to claim 2, wherein forming the interconnect wiring comprises:
providing a second carrier wafer and forming the interconnect wiring on the second carrier wafer,
wherein forming the re-distribution layer structure further comprises forming conductive bumps on the conductive plug and the soldering pads of the functional components and bonding the interconnect wiring on the conductive bumps.

6. The method according to claim 1, wherein forming the conductive bumps on the interconnect wiring comprises:
forming a second dielectric layer to cover the second carrier wafer and the interconnect wiring;
patterning the second dielectric layer to form an interconnect via in the second dielectric layer to expose the interconnect wiring;
forming the conductive bump in the interconnect via; and
removing the second dielectric layer.

7. The method according to claim 3, wherein forming the interconnect wiring comprises:
forming a third dielectric layer to cover the encapsulation layer and the filter and in the conducive via after forming the conductive via;
patterning the third dielectric layer to remove a portion of the third dielectric layer in the conductive via and a portion of the third dielectric layer above the encapsulation layer to form a second interconnect trench exposing the soldering pad of the functional component and connecting with the second interconnect trench;
forming the interconnect wiring in the conductive via during forming the conductive plug in the conductive via; and
removing the third dielectric layer.

8. The method according to claim 2, wherein:
the conductive bumps are formed by a reballing process.

9. The method according to claim 1, before forming the encapsulation layer, further comprising:
forming a stress buffer layer to cover the sidewall surfaces of the filter.

10. The method according to claim 1, wherein forming the encapsulation layer comprises:
forming an encapsulation material layer to cover the first carrier wafer, the functional components and the photosensitive chip; and
planarizing the encapsulation material layer to form the encapsulation layer leveling with a highest one of the photosensitive unit and the functional components.

11. The method according to claim 1, after forming the re-distribution layer structure on the side of the encapsulation layer adjacent to the filter, further comprising:
bonding a flexible printed circuit board (FPC) on the re-distribution structure.

12. A camera assembly, comprising:
an encapsulation layer; and
a photosensitive unit and functional components, embedded in the encapsulation layer, wherein:
the photosensitive unit includes a photosensitive chip and a filter mounted on the photosensitive chip,
a top surface of the encapsulation layer exposes the filter and the functional components,
a bottom of the encapsulation layer is higher than the functional components,
the encapsulation layer at least covers portions of sidewall surfaces of the photosensitive chip,
the photosensitive chip and the functional components all contains soldering pads,
the soldering pad of the photosensitive chip faces the top surface of the encapsulation layer and
the soldering pads of the functional components are exposed on the top surface of the encapsulation layer; and
a re-distribution layer structure disposed on a side of the encapsulation layer adjacent to the filter and electrically connecting to the soldering pads.

13. The camera assembly according to claim 12, wherein the re-distribution layer structure comprises:
a conductive plug, disposed in the encapsulation layer and electrically connected to the soldering pad of the photosensitive chip; and
an interconnect wiring, disposed on the functional components and the conductive plug, and electrically connect the soldering pads of the functional components and the conductive plug.

14. The camera assembly according to claim 13, wherein the re-distribution layer structure further comprises:
conductive bumps disposed between the interconnect wiring and the soldering pads of the functional components and the conductive plug.

15. The camera assembly according to claim 12, wherein:
the encapsulation layer levels with a highest one of the photosensitive unit and the functional components.

16. The camera assembly according to claim 12, further comprising:
a stress buffer layer, disposed between sidewall surfaces of the filter and the encapsulation layer.

17. The camera assembly according to claim 12, wherein:
the functional component includes at least one of a peripheral chip and a passive component; and
the peripheral chip includes at least one of a digital signal processing chip and a memory chip.

18. The camera assembly according to claim 12, further comprising:
a flexible printed circuit board (FPC) disposed on the re-distribution layer structure.

19. A lens module, comprising:
a camera assembly, including an encapsulation layer, and a photosensitive unit and functional components embedded in the encapsulation layer, and a re-distribution layer structure disposed on a side of the encapsulation layer adjacent to the filter and electrically connecting the soldering pads,
wherein the photosensitive unit includes a photosensitive chip and a filter mounted on the photosensitive chip, a top surface of the encapsulation layer exposes the filter and the functional components, a bottom of the encapsulation layer is higher than the functional components, the encapsulation layer at least covers portions of sidewall surfaces of the photosensitive chip, the photosensitive chip and the functional components all contains soldering pads, the soldering pad of the photosensitive chip faces the top surface of the encapsulation layer and the soldering pads of the functional components are exposed on the top surface of the encapsulation layer; and
a lens assembly, including a support mounted on the top surface of the encapsulation layer and surrounding the photosensitive unit and the functional components, and electrically connected to the photosensitive chip and the functional components.

20. An electronic device, comprising the lens module according to claim 19:
